(19) United States
(12) Patent Application Publication
(10) Pub. No.: US 2025/0212595 A1
(43) Pub. Date: Jun. 26, 2025

(54) DISPLAY APPARATUS HAVING A LIGHT-EMITTING DEVICE

(71) Applicant: LG Display Co., Ltd., Seoul (KR)

(72) Inventors: Yu Jeong LEE, Paju-si (KR); Eun Jung PARK, Paju-si (KR); Chun Ki KIM, Paju-si (KR); Ju Hyuk KWON, Paju-si (KR); Jang Dae YOUN, Paju-si (KR); Hyun Jin CHO, Paju-si (KR); Jun Su HA, Paju-si (KR)

(73) Assignee: LG Display Co., Ltd., Seoul (KR)

(21) Appl. No.: 18/889,100

(22) Filed: Sep. 18, 2024

(30) Foreign Application Priority Data
Dec. 22, 2023 (KR) 10-2023-0190251

(51) Int. Cl. H10K 50/115; C09K 11/06; H10K 50/12; H10K 50/13; H10K 50/15; H10K 50/18; H10K 59/38; H10K 85/60; H10K 101/40; H10K 102/00

(52) U.S. Cl. CPC H10K 50/115; C09K 11/06; H10K 50/12; H10K 50/13; H10K 50/15; H10K 50/181; H10K 59/38; H10K 85/615; H10K 85/633; H10K 2101/40; H10K 2102/351

(57) ABSTRACT

A display apparatus can include a light-emitting unit including a hole transport layer, an anti-degradation layer, an electron blocking layer and a blue emission material layer stacked on a lower electrode. The display apparatus can further include an upper electrode disposed on the light-emitting unit, the upper electrode having a lower work-function than the lower electrode, in which the blue emission material layer includes a blue dopant, and the anti-degradation layer is made of a fluorescent dopant in which an amine monomer is substituted in a core.

### CROSS-REFERENCE TO RELATED APPLICATIONS

This application claims priority to Korean Patent Application No. 10-2023-0190251, filed in the Republic of Korea on Dec. 22, 2023, the entirety of which is hereby incorporated by reference into the present application as if fully set forth herein.

### BACKGROUND

### Field of the Invention

The present disclosure relates to a display apparatus in which a light-emitting device is disposed on each pixel area.

### Discussion of the Related Art

Generally, a display apparatus provides an image to a user. For example, the display apparatus can include light-emitting devices. Each of the light-emitting devices can be disposed on one of the pixel areas. Each of the pixel areas can realize a specific color. For example, the light-emitting device of each pixel area can include a light-emitting unit between two electrodes.

At least one of the light-emitting devices can include a blue emission material layer. For example, at least one of the light-emitting devices can include a hole transport layer, an electron blocking layer, a blue emission material layer, an electron transport layer and an upper electrode, which are sequentially stacked on a lower electrode. The upper electrode can have a lower work function than the lower electrode. For example, the blue emission material layer can generate and emit light displaying blue color using holes supplied from the lower electrode and electrons supplied from the upper electrode.

The electron blocking layer can prevent electrons supplied from the upper electrode from moving toward the hole transport layer. For example, a lowest unoccupied molecular orbital (LUMO) energy level of the electron blocking layer can have an absolute value smaller than a LUMO energy level of the blue emission material layer. A highest occupied molecular orbital (HOMO) energy level of the electron blocking layer can have an absolute value that is greater than a HOMO energy level of the hole transport layer. Thus, in the display apparatus, the movement of holes passing through the hole transport layer can be delayed by the electron blocking layer. That is, in the display apparatus, holes can be accumulated at a boundary between the hole transport layer and the electron blocking layer. And, in the display apparatus, electrons passing through the blue emission material layer can be accumulated at a boundary between the hole transport layer and the electron blocking layer. Therefore, in the display apparatus, the hole transport layer and/or the electron blocking layer can become deteriorated over time by holes and electrons accumulated in the light-emitting unit, which can impair brightness, reduce image color quality, and reduce the lifespan of the display apparatus.

Thus, there exists a need for a light-emitting unit that has a configuration that can improve the flow of holes and electrons, direct the formation of excitons at the appropriate layer(s), increase brightness, increase lifespan, reduce power and improve color quality.

### SUMMARY OF THE DISCLOSURE

Accordingly, the present disclosure is directed to a display apparatus that substantially obviates one or more problems due to limitations and disadvantages of the related art.

An object of the present disclosure is to provide a display apparatus capable of improving life-time and efficiency of the light-emitting unit including the blue emission material layer.

Another object of the present disclosure is to provide a display apparatus capable of preventing the accumulation of holes and electrons between the hole transport layer and the electrode blocking layer of the light-emitting unit including the blue emission material layer.

Additional advantages, objects, and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description and claims hereof as well as the appended drawings.

To achieve these objects and other advantages and in accordance with the purpose of the present disclosure, as embodied and broadly described herein, there is provided a display apparatus including a lower electrode, in which a light-emitting unit is disposed on the lower electrode. The light-emitting unit includes a hole transport layer, an anti-degradation layer, an electron blocking layer and a blue emission material layer, which are sequentially stacked. The blue emission material layer includes a blue dopant. The anti-degradation layer is made of a fluorescent dopant in which an amine monomer is substituted in a core. An upper electrode is disposed on the light-emitting unit. The upper electrode has a lower work-function than the lower electrode.

The anti-degradation layer can be in contact with the hole transport layer and the electron blocking layer. The anti-degradation layer can have a HOMO energy level between a HOMO energy level of the hole transport layer and a HOMO energy level of the electron blocking layer.

The anti-degradation layer can have a smaller thickness than the electron blocking layer.

The thickness of the anti-degradation layer can be approximately 30 Å to 50 Å (e.g., 40 Å).

The fluorescent dopant can include a different material from the blue dopant.

The fluorescent dopant can be an anthracene derivative in which an aromatic amine monomer is substituted in an anthracene core.

The fluorescent dopant can be a green fluorescent dopant represented by one of the formulas 1 to 3 below.

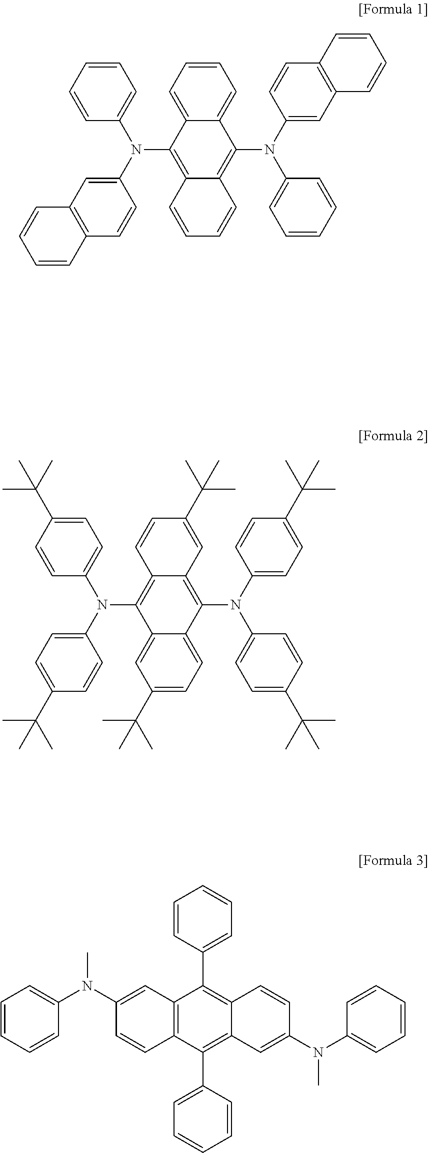 [SMILES: c1ccc(N(c2ccc3ccccc3c2)c2c3ccccc3c(N(c3ccccc3)c3ccc4ccccc4c3)c3ccccc23)cc1 ; CC(C)(C)c1ccc(N(c2ccc(C(C)(C)C)cc2)c2c3ccc(C(C)(C)C)cc3c(N(c3ccc(C(C)(C)C)cc3)c3ccc(C(C)(C)C)cc3)c3ccc(C(C)(C)C)cc23)cc1 ; CN(c1ccccc1)c1ccc2c(-c3ccccc3)c3cc(N(C)c4ccccc4)ccc3c(-c3ccccc3)c2c1]

A blue color filter can be disposed on the upper electrode. A transmittance of the upper electrode can be greater than a transmittance of the lower electrode.

In another embodiment, there is provided a display apparatus including a device substrate, in which a first lower electrode is disposed on a first pixel area of the device substrate. A light-emitting unit is disposed on the first lower electrode, and an upper electrode is disposed on the light-emitting unit. An encapsulation structure is disposed on the upper electrode. The light-emitting unit includes a first emission stack, a second emission stack and a first charge generation layer. The second emission stack generates light displaying a different color from the first emission stack. The first charge generation layer is disposed between the first emission stack and the second emission stack. The first emission stack includes a first hole transport layer, a first anti-degradation layer, a first electron blocking layer and a first blue emission material layer. The first electron blocking layer is disposed between the first hole transport layer and the first blue emission material layer. The first anti-degradation layer is disposed between the first hole transport layer and the first electron blocking layer. The first anti-degradation layer includes a first fluorescent dopant in which an amine monomer is substituted in a core.

The second emission stack can include a green emission material layer and a red emission material layer. The green emission material layer can include a green phosphorescent dopant. The red emission material layer can include a red phosphorescent dopant.

The light-emitting unit can include a third emission stack and a second charge generation layer. The third emission stack can include a second blue emission material layer. The second charge generation layer can be disposed between the second emission stack and the third emission stack. Each of the first blue emission material layer and the second blue emission material layer can include a blue dopant. The blue dopant can include a different material from the first fluorescent dopant.

The blue dopant of the second blue emission material layer can include a same material as the blue dopant of the first blue emission material layer.

The third emission stack can include a second hole transport layer, a second electron blocking layer, and a second anti-degradation layer. The second electron blocking layer can be disposed between the second hole transport layer and the second blue emission material layer. The second anti-degradation layer can be disposed between the second hole transport layer and the second electron blocking layer. The second anti-degradation layer can include a second fluorescent dopant in which an amine monomer is substituted in a core.

The second fluorescent dopant can include a same material as the first fluorescent dopant.

A second lower electrode can be disposed on a second pixel area of the device substrate. In the light-emitting unit, the upper electrode and the encapsulation structure can extend on the second lower electrode. A first color filter and a second color filter can be disposed on the encapsulation structure. The first color filter can overlap with an emission area of the first pixel area. The second color filter can overlap with an emission area of the second pixel area. The second color filter can include a different material than the first color filter.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a view schematically showing a display apparatus according to an embodiment of the present disclosure;

FIG. 2 is a view showing a circuit of a pixel area in the display apparatus according to the embodiment of the present disclosure;

FIG. 3 is a view showing a cross-section of the pixel areas in the display apparatus according to the embodiment of the present disclosure;

FIG. 4 is an enlarged view of K1 region in FIG. 3 according to an embodiment of the present disclosure;

FIG. 5 is a view showing an energy band diagram of a hole transport layer, an anti-degradation layer, an electron blocking layer and a blue emission material layer of a blue pixel region in the display apparatus according to the embodiment of the present invention;

FIG. 6 is a graph showing relative intensity according to a wavelength of light emitted from a blue pixel area for each structure of a light-emitting unit according to the embodiment of the present invention; and

FIGS. 7 to 13 are views showing the display apparatus according to another embodiment of the present disclosure.

### DETAILED DESCRIPTION OF THE EMBODIMENTS

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure can be embodied in other forms and is not limited to the embodiments described below.

In addition, the same or extremely similar elements can be designated by the same reference numerals throughout the specification and in the drawings, the lengths and thickness of layers and regions can be exaggerated for convenience. It will be understood that, when a first element is referred to as being “on” a second element, although the first element can be disposed on the second element to come into contact with the second element, a third element can be interposed between the first element and the second element.

Here, terms such as, for example, “first” and “second” can be used to distinguish any one element with another element. However, the first element and the second element can be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless “directly” is used, the terms “connected” and “coupled” can include that two components are “connected” or “coupled” through one or more other components located between the two components.

The features of various embodiments of the present disclosure can be partially or entirely coupled to or combined with each other and can be interlocked and operated in technically various ways, and the embodiments can be carried out independently of or in association with each other.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

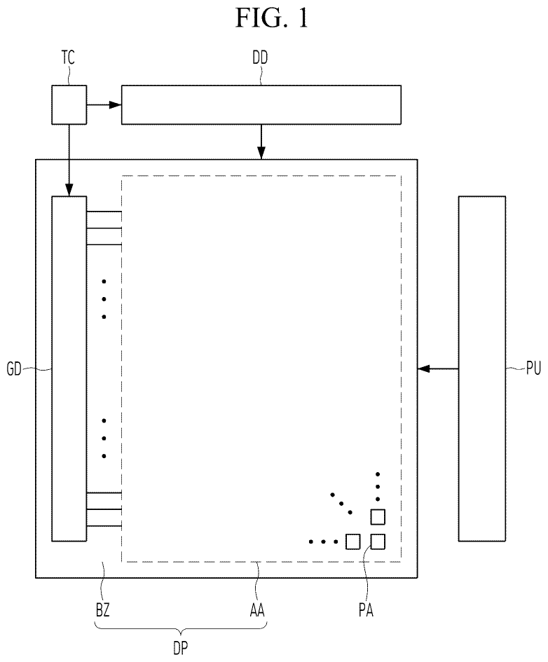

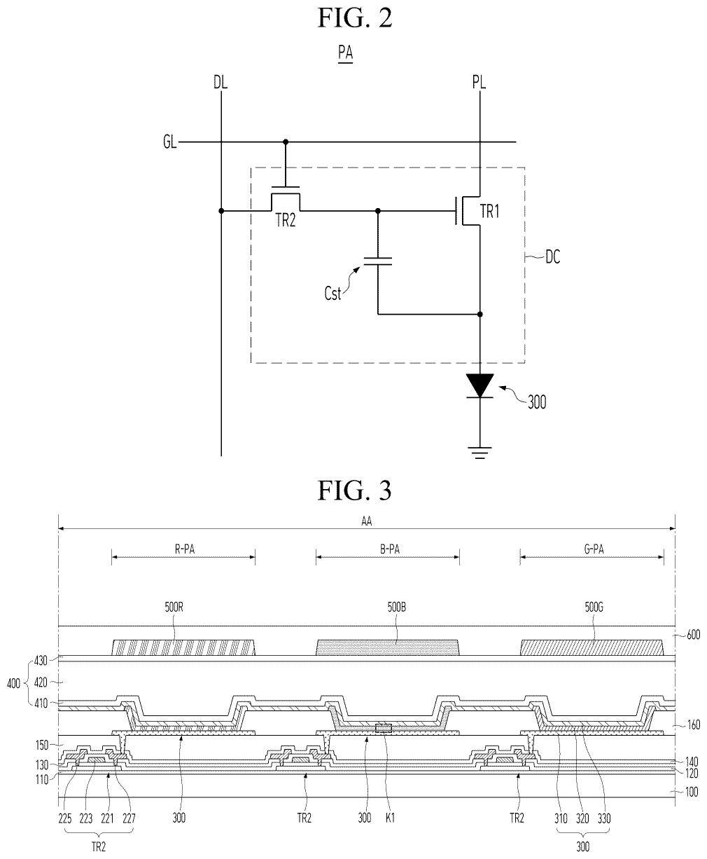

FIG. 1 is a view schematically showing a display apparatus according to an embodiment of the present disclosure. FIG. 2 is a view showing a circuit of a pixel area in the display apparatus according to the embodiment of the present disclosure.

Referring to FIGS. 1 and 2, the display apparatus according to the embodiment of the present disclosure can include a display panel DP. The display panel DP can generate an image provided to a user. For example, a plurality of pixel area PA can be disposed in the display panel DP. Each of the pixel areas PA can be disposed in one of areas defined by signal wirings GL, DL and PL. For example, each of the pixel areas PA can be surrounded by the signal wirings GL, DL and PL. The signal wirings GL, DL and PL can provide various signals to each pixel area PA. For example, the signal wirings GL, DL and PL can include gate lines GL sequentially applying a gate signal, data lines DL applying a data signal, and power voltage supply lines PL supplying a power voltage.

The gate lines GL can be electrically connected to a gate driver GD. The data lines DL can be electrically connected to a data driver DD. The power voltage supply lines PL can be electrically connected to a power unit PU. The gate driver GD and the data driver DD can be controlled by a timing controller TC. For example, the gate driver GD can receive clock signals, reset signals and a start signal from the timing controller TC, and the data driver DD can receive digital video data and a source timing signal from the timing controller TC.

The display panel DP can include an active area AA in which the pixel areas PA are disposed, and a bezel area BZ disposed outside the active area AA. The bezel area BZ can be disposed outside the pixel areas PA. For example, the active area AA can be surrounded by the bezel area BZ. The gate driver GD, the data driver DD, the power unit PU and the timing controller TC can be disposed outside the active area AA. For example, each of the signal wiring GL, DL and PL can include a portion disposed on the bezel area BZ.

At least one of the gate driver GD, the data driver DD, the power unit PU and the timing controller TC can be disposed on the bezel area BZ. For example, the display apparatus according to the embodiment of the present disclosure can be a GIP (Gate In Panel) type display apparatus in which the gate driver GD is formed on the bezel area BZ.

Each of the pixel areas PA can realize a specific color according to signals applied through the signal wirings GL, DL and PL. For example, a driving circuit DC electrically connected to a light-emitting device 300 can be disposed in each pixel area PA. The driving circuit DC of each pixel area PA can be electrically connected to the signal wirings GL, DL and PL. For example, the driving circuit DC of each pixel area PA can be electrically connected to one of the gate lines GL, one of the data lines DL and one of the power voltage supply lines PL. The driving circuit DC of each pixel area PA can supply a driving current corresponding to the data signal to the light-emitting device 300 of the corresponding pixel area PA according to the gate signal for one frame. For example, the driving circuit DC of each pixel area PA can include a first thin film transistor TR1, a second thin film transistor TR2 and a storage capacitor Cst.

FIG. 3 is a view showing a cross-section of the pixel areas in the display apparatus according to the embodiment of the present disclosure.

Referring to FIGS. 2 and 3, the first thin film transistor TR1 of each pixel area PA, R-PA, G-PA and B-PA can transmit the data signal to the second thin film transistor TR2 of the corresponding pixel area PA, R-PA, G-PA and B-PA according to the gate signal. For example, the first thin film transistor TR1 of each pixel area PA, R-PA, G-PA and B-PA can be a switching thin film transistor. The first thin film transistor TR1 of each pixel area PA, R-PA, G-PA and B-PA can include a first semiconductor pattern, a first gate electrode, a first drain electrode and a first source electrode. For example, the first gate electrode of each pixel area PA, R-PA, G-PA and B-PA can be electrically connected to the corresponding gate line GL, and the first drain electrode of each pixel area PA, R-PA, G-PA and B-PA can be electrically connected to the corresponding date line DL.

The first semiconductor pattern can include a semiconductor material. For example, the first semiconductor pattern can include amorphous silicon (a-Si), polycrystalline silicon (poly-Si) or an oxide semiconductor, such as IGZO. The first semiconductor pattern can include a first drain region, a first channel region and a first source region. The first channel region can be disposed between the first drain region and the first source region. The first drain region and the first source region can have a smaller resistance than the first channel region. For example, the first drain region and the first source region can include a conductive region of an oxide semiconductor. The first channel region can be a region of an oxide semiconductor, which is not conductorized.

The first gate electrode can be disposed on a portion of the first semiconductor pattern. For example, the first gate electrode can overlap with the first channel region of the first semiconductor pattern. The first gate electrode can include a conductive material. For example, the first gate electrode can include a metal, such as aluminum (Al), chrome (Cr), copper (Cu), molybdenum (Mo), titanium (Ti) and tungsten (W). The first gate electrode can be spaced apart from the first semiconductor pattern. The first gate electrode can be insulated from the first semiconductor pattern. For example, the first drain region of the first semiconductor pattern can be electrically connected to the first source region of the first semiconductor pattern according to a voltage applied to the first gate electrode.

The first drain electrode can include a conductive material. For example, the first drain electrode can include a metal, such as aluminum (Al), chrome (Cr), copper (Cu), molybdenum (Mo), titanium (Ti) and tungsten (W). The first drain electrode can include a different material from the first gate electrode. For example, the first drain electrode can be disposed on a different layer from the first gate electrode. The first drain electrode can be electrically connected to the first drain region of the first semiconductor pattern. The first drain electrode can be insulated from the first gate electrode.

The first source electrode can include a conductive material. For example, the first source electrode can include a metal, such as aluminum (Al), chrome (Cr), copper (Cu), molybdenum (Mo), titanium (Ti) and tungsten (W). The first source electrode can include a different material from the first gate electrode. The first source electrode can be disposed on a different layer from the first gate electrode. For example, the first source electrode can be disposed on a same layer as the first drain electrode. The first source electrode can include a same material as the first drain electrode. The first source electrode can be formed by a same process as the first drain electrode. For example, the first source electrode can be formed simultaneously with the first drain electrode. The first source electrode can be electrically connected to the first source region of the first semiconductor pattern. The first source electrode can be insulated from the first gate electrode. The first source electrode can be spaced apart from the first drain electrode.

The second thin film transistor TR2 of each pixel area PA, R-PA, G-PA and B-PA can generate the driving current corresponding to the data signal. For example, the second thin film transistor TR2 of each pixel area PA, R-PA, G-PA and B-PA can be a driving thin film transistor. The second thin film transistor TR2 of each pixel area PA, R-PA, G-PA and B-PA can include a second semiconductor pattern 221, a second gate electrode 223, a second drain electrode 225 and a second source electrode 227. For example, the second gate electrode 223 of each pixel area PA, R-PA, G-PA and B-PA can be electrically connected to the first source electrode of the corresponding pixel area PA, R-PA, G-PA and B-PA, and the second drain electrode 225 of each pixel area PA, R-PA, G-PA and B-PA can be electrically connected to the corresponding power voltage supply line PL.

The second semiconductor pattern 221 can include a semiconductor material. For example, the second semiconductor pattern 221 can include amorphous silicon (a-Si), polycrystalline silicon (poly-Si) or an oxide semiconductor, such as IGZO. The second semiconductor pattern 221 can include a same material as the first semiconductor pattern. The second semiconductor pattern 221 can be disposed on a same layer as the first semiconductor pattern. The second semiconductor pattern 221 can be formed by a same process as the first semiconductor pattern. For example, the second semiconductor pattern 221 can be formed simultaneously with the first semiconductor pattern.

The second semiconductor pattern 221 can include a second drain region, a second channel region and a second source region. The second channel region can be disposed between the second drain region and the second source region. The second drain region and the second source region can have a lower resistance than the second channel region. For example, the second drain region and the second source region can include a conductive region of an oxide semiconductor. The second channel region can be a region of an oxide semiconductor, which is not conductorized.

The second gate electrode 223 can be disposed on a portion the second semiconductor pattern 221. For example, the second gate electrode 223 can overlap with the second channel region of the second semiconductor pattern 221. The second gate electrode 223 can include a conductive material. For example, the second gate electrode 223 can include a metal, such as aluminum (Al), chrome (Cr), copper (Cu), molybdenum (Mo), titanium (Ti) and tungsten (W). The second gate electrode 223 can be spaced apart from the second semiconductor pattern 221. The second gate electrode 223 can be insulated from the second semiconductor pattern 221. For example, the second channel region of the second semiconductor pattern 221 can have an electrical conductivity corresponding to a voltage applied to the second gate electrode 223.

The second drain electrode 225 can include a conductive material. For example, the second drain electrode 225 can include a metal, such as aluminum (Al), chrome (Cr), copper (Cu), molybdenum (Mo), titanium (Ti) and tungsten (W). The second drain electrode 225 can include a different material from the second gate electrode 223. For example, the second drain electrode 225 can be disposed on a different layer from the second gate electrode 223. The second drain electrode 225 can be electrically connected to the second drain region of the second semiconductor pattern 221. The second drain electrode 225 can be insulated from the second gate electrode 223.

The second drain electrode 225 can include a same material as the first drain electrode. The second drain electrode 225 can be disposed on a same layer as the first drain electrode. The second drain electrode 225 can be formed by a same process as the first drain electrode. For example, the second drain electrode 225 can be formed simultaneously with the first drain electrode.

The second source electrode 227 can include a conductive material. For example, the second source electrode 227 can include a metal, such as aluminum (Al), chrome (Cr), copper (Cu), molybdenum (Mo), titanium (Ti) and tungsten (W). The second source electrode 227 can include a different material from the second gate electrode 223. The second source electrode 227 can be disposed on a different layer from the second gate electrode 223. For example, the second source electrode 227 can be disposed on a same layer as the second drain electrode 225. The second source electrode 227 can include a same material as the second drain electrode 225. The second source electrode 227 can be formed by a same process as the second drain electrode 225. For example, the second source electrode 227 can be formed simultaneously with the second drain electrode 225. The second source electrode 227 can be electrically connected to the second source region of the second semiconductor pattern 221. The second source electrode 227 can be insulated from the second gate electrode 223. The second source electrode 227 can be spaced apart from the second drain electrode 225.

The storage capacitor Cst of each pixel area PA, R-PA, G-PA and B-PA can maintain a signal applied to the second gate electrode 223 of the corresponding pixel area PA, R-PA, G-PA and B-PA for one frame. For example, the storage capacitor Cst of each pixel area

PA, R-PA, G-PA and B-PA can be electrically connected between the second gate electrode 223 and the second source electrode 227 of the corresponding pixel area PA, R-PA, G-PA and B-PA. The storage capacitor Cst of each pixel area PA, R-PA, G-PA and B-PA can have a stacked structure of multiple capacitor electrodes (e.g., two or more capacitor electrodes). For example, the storage capacitor Cst of each pixel area PA, R-PA, G-PA and B-PA can include a first capacitor electrode electrically connected to the second gate electrode 233 of the corresponding pixel area PA, R-PA, G-PA and B-PA, and a second capacitor electrode electrically connected to the second source electrode 227 of the corresponding pixel area PA, R-PA, G-PA and B-PA.

The storage capacitor Cst of each pixel area PA, R-PA, G-PA and B-PA can be formed by using a process of forming the first thin film transistor TR1 and the second thin film transistor TR2 of the corresponding pixel area PA, R-PA, G-PA and B-PA. For example, the first capacitor electrode of each pixel area PA, R-PA, G-PA and B-PA can be disposed on a same layer as the second gate electrode 223 of the corresponding pixel area PA, R-PA, G-PA and B-PA, and the second capacitor electrode of each pixel area PA, R-PA, G-PA and B-PA can be disposed on a same layer as the second source electrode 227 of the corresponding pixel area PA, R-PA, G-PA and B-PA. The first capacitor electrode of each pixel area PA, R-PA, G-PA and B-PA can include a same material as the second gate electrode 223 of the corresponding pixel area PA, R-PA, G-PA and B-PA, and the second capacitor electrode of each pixel area PA, R-PA, G-PA and B-PA can include a same material as the second source electrode 227 of the corresponding pixel area PA, R-PA, G-PA and B-PA. The first capacitor of each pixel area PA, R-PA, G-PA and B-PA can be formed by a same process as the second gate electrode 223 of the corresponding pixel area PA, R-PA, G-PA and B-PA, and the second capacitor electrode of each pixel area PA, R-PA, G-PA and B-PA can be formed by a same process as the second source electrode 227 of the corresponding pixel area PA, R-PA, G-PA and B-PA. For example, the first capacitor electrode of each pixel area PA, R-PA, G-PA and B-PA can be formed simultaneously with the second gate electrode 223 of the corresponding pixel area PA, R-PA, G-PA and B-PA, and the second capacitor electrode of each pixel area PA, R-PA, G-PA and B-PA can be formed simultaneously with the second source electrode 227 of the corresponding pixel area PA, R-PA, G-PA and B-PA.

The driving circuit DC and the light-emitting device 300 of each pixel area PA, R-PA, G-PA and B-PA can be supported by a device substrate 100. For example, the first thin film transistor TR1, the second thin film transistor TR2 and the storage capacitor Cst of each pixel area PA, R-PA, G-PA and B-PA can be disposed on the corresponding pixel area PA, R-PA, G-PA and B-PA of the device substrate 100. The device substrate 100 can include an insulating material. The device substrate t100 can include a transparent material. For example, the device substrate 100 can include glass or plastic.

A plurality of insulating layers 110, 120, 130, 140, 150 and 160 for preventing unnecessary electrical connection can be disposed on the device substrate 100. For example, a buffer insulating layer 110, a gate insulating layer 120, an interlayer insulating layer 130, a device passivation layer 140, a planarization layer 150 and a bank insulating layer 160 can be disposed on the device substrate 100.

The buffer insulating layer 110 can be disposed close to the device substrate 100. The buffer insulating layer 110 can prevent outgassing or pollution due to the device substrate 100 in a process of forming the driving circuit DC of each pixel area PA, R-PA, G-PA and B-PA. For example, an upper surface of the device substrate 100 toward the driving circuit DC of each pixel area PA, R-PA, G-PA and B-PA can be completely covered by the buffer insulating layer 110. The driving circuit DC of each pixel area PA, R-PA, G-PA and B-PA can be disposed on the buffer insulating layer 110. The buffer insulating layer 110 can include an insulating material. For example, the buffer insulating layer 110 can include an inorganic insulating material, such as silicon oxide (SiOx) and silicon nitride (SiNx). The buffer insulating layer 110 can have a multi-layer structure. For example, the buffer insulating layer 110 can have a structure in which an inorganic insulating layer made of silicon oxide (SiOx) and an inorganic insulating layer made of silicon nitride (SiNx) are alternately stacked.

The gate insulating layer 120 can be disposed on the buffer insulating layer 110. The first gate electrode of each pixel area PA, R-PA, G-PA and B-PA can be insulated from the first semiconductor pattern of the corresponding pixel area PA, R-PA, G-PA and B-PA by the gate insulating layer 120. The second gate electrode 223 of each pixel area PA, R-PA, G-PA and B-PA can be insulated from the second semiconductor pattern 221 of the corresponding pixel area PA, R-PA, G-PA and B-PA by the gate insulating layer 120. For example, the gate insulating layer 120 can cover the first semiconductor pattern and the second semiconductor pattern 221 of each pixel area PA, R-PA, G-PA and B-PA. The first gate electrode and the second gate electrode 223 of each pixel area PA, R-PA, G-PA and B-PA can be disposed on the gate insulating layer 120. The gate insulating layer 120 can include an insulating material. For example, the gate insulating layer 120 can include an inorganic insulating material, such as silicon oxide (SiOx) and silicon nitride (SiNx).

The interlayer insulating layer 130 can be disposed on the gate insulating layer 120. The first drain electrode and the first source electrode of each pixel area PA, R-PA, G-PA and B-PA can be insulated from the first gate electrode of the corresponding pixel area PA, R-PA, G-PA and B-PA by the interlayer insulating layer 130. The second drain electrode 225 and the second source electrodes 227 of each pixel area PA, R-PA, G-PA and B-PA can be insulated from the second gate electrode 223 of the corresponding pixel area PA, R-PA, G-PA and B-PA by the interlayer insulating layer 130. For example, the interlayer insulating layer 130 can cover the first gate electrode and the second gate electrode 223 of each pixel area PA, R-PA, G-PA and B-PA. The first drain electrode, the first source electrode, the second drain electrode 225 and the second source electrode 227 of each pixel area PA, R-PA, G-PA and B-PA can be disposed on the interlayer insulating layer 130. The interlayer insulating layer 130 can include an insulating material. For example, the interlayer insulating layer 130 can include an inorganic insulating material.

The device passivation layer 140 can be disposed on the interlayer insulating layer 130. The device passivation layer 140 can prevent damage of the driving circuit DC in each pixel area PA, R-PA, G-PA and B-PA due to external impact and moisture. For example, the driving circuit DC of each pixel area PA, R-PA, G-PA and B-PA can be covered by the device passivation layer 140. The device passivation layer 140 can cover the first drain electrode, the first source electrode, the second drain electrode 225 and the second source electrode 227 of each pixel area PA, R-PA, G-PA and B-PA. The device passivation layer 140 can include an insulating material. For example, the device passivation layer 140 can be an inorganic insulating material.

The planarization layer 150 can be disposed on the device passivation layer 140. The planarization layer 150 can remove a thickness difference or step differences due to the driving circuit DC of each pixel area PA, R-PA, G-PA and B-PA. For example, an upper surface of the planarization layer 150 opposite to the device substrate 100 can be a flat surface. The upper surface of the planarization layer 150 can be parallel to the upper surface of the device substrate 100. The planarization layer 150 can include an insulating material. The planarization layer 150 can include a different material than the device passivation layer 140.

The planarization layer 150 can include a material having a relatively high fluidity. For example, the planarization layer 150 can include an organic insulating material.

The light-emitting device 300 of each pixel area PA, R-PA, G-PA and B-PA can be disposed on the planarization layer 150. The light-emitting device 300 of each pixel area PA, R-PA, G-PA and B-PA can emit light displaying a specific color. For example, the light-emitting device 300 of each pixel area PA, R-PA, G-PA and B-PA can include a lower electrode 310, a light-emitting unit 320 and an upper electrode 330, which are sequentially stacked on the planarization layer 150 of the corresponding pixel area PA, R-PA, G-PA and B-PA.

The lower electrode 310 can include a conductive material. The lower electrode 310 can include a material having a relatively higher reflectance for extracting more light out of the display device and towards a user's eyes. For example, the lower electrode 310 can include a metal, such as aluminum (Al) and silver (Ag). The lower electrode 310 can have a multi-layer structure. For example, the lower electrode 310 can have a structure in which a reflective electrode made of a metal is disposed between transparent electrodes made of a transparent conductive material, such as ITO and IZO.

The light-emitting unit 320 (e.g., the light-emitting unit can also be referred to as a light-emitting device) can generate light having luminance corresponding to a voltage difference between the lower electrode 310 and the upper electrode 330. For example, the light-emitting unit 320 can include an emission material layer (EML). The emission material layer can generate light using energy by recombination of electrons and holes. For example, The emission material layer can include a host and a dopant doped in the host. Here, the term ‘doped’ means that a second material having physical properties different from a first material was added to a layer in which the first material occupies most of the weight ratio. For example, the dopant of the emission material layer can have a weight ratio of less than 30% of the emission material layer. Also, a Lowest Unoccupied Molecular Orbital (LUMO) energy level and a Highest Occupied Molecular Orbital (HOMO) energy level of the emission material layer can mean a LUMO energy level and a HOMO energy level of the host occupying most of the weight ratio in the emission material layer.

The light-emitting unit 320 can have a multi-layer structure. For example, the light-emitting unit 320 can further include at least one of a hole injection layer (HIL), a hole transport layer (HTL), an electron transport layer (ETL) and an electron injection layer (EIL). Thus, in the display apparatus according to the embodiment of the present disclosure, efficiency of the light-emitting unit 320 can be improved and the light-emitting unit 320 can be brighter.

The upper electrode 330 can include a conductive material. The upper electrode 330 can include a different material than the lower electrode 310. A transmittance of the upper electrode 330 can be higher than a transmittance of the lower electrode 310. For example, the upper electrode 330 can be a transparent electrode made of a transparent conductive material, such as ITO and IZO, or a translucent electrode in which metals such as Ag and Mg are thinly formed. Thus, in the display apparatus according to the embodiment of the present disclosure, the light generated by the light-emitting unit 320 can be emitted outside through the upper electrode 330. Also, the upper electrode 330 can have a lower work function than the lower electrode 310. For example, the lower electrode 310 can function as an anode electrode, and the upper electrode 330 can function as a cathode electrode. For example, electrons can more easily flow from the upper electrode 330 to the lower electrode 310.

The light-emitting device 300 of each pixel area PA, R-PA, G-PA and B-PA can be electrically connected to the second thin film transistor TR2 of the driving circuit DC in the corresponding pixel area PA, R-PA, G-PA and B-PA. For example, the lower electrode 310 of each pixel area PA, R-PA, G-PA and B-PA can be in direct contact with the second source electrode 227 of the corresponding pixel area PA, R-PA, G-PA and B-PA by penetrating through the planarization layer 150 (e.g., via a contact hole). The lower electrode 310 of each pixel area PA, R-PA, G-PA and B-PA can include a region being in direct contact with the upper surface of the planarization layer 150. For example, the light-emitting unit 320 and the upper electrode 330 of each pixel area PA, R-PA, G-PA and B-PA can be stacked on a region of the corresponding lower electrode 310 being in direct contact with the upper surface of the planarization layer 150.

The bank insulating layer 160 can be disposed on the planarization layer 150. The bank insulating layer 160 can include an insulating material. For example, the bank insulating layer 160 can be an organic insulating material. The bank insulating layer 160 can include a different material than the planarization layer 150. The bank insulating layer 160 can define an emission area in each pixel area PA, R-PA, G-PA and B-PA. A portion of the lower electrode 310 in each pixel area PA, R-PA, G-PA and B-PA can be exposed by the bank insulating layer 160. For example, an edge of the lower electrode 310 in each pixel area PA, R-PA, G-PA and B-PA can be covered by or at least partially overlapped by the bank insulating layer 160. Thus, in the display apparatus according to the embodiment of the present disclosure, the lower electrode 310 of each pixel area PA, R-PA, G-PA and B-PA can be insulated from the lower electrode 310 of adjacent pixel area PA, R-PA, G-PA and B-PA by the bank insulating layer 160.

A portion of the lower electrode 310 exposed by the bank insulating layer 160 in each pixel area PA, R-PA, G-PA and B-PA can overlap with the emission area of the corresponding pixel area PA, R-PA, G-PA and B-PA. A portion of the lower electrode 310 overlapping with the emission area in each pixel area PA, R-PA, G-PA and B-PA can be in direct contact with the upper surface of the planarization layer 150. That is, in the display apparatus according to the embodiment of the present invention, the light-emitting unit 320 and the upper electrode 330 of each pixel area PA, R-PA, G-PA and B-PA can be stacked on the emission area of the corresponding pixel area PA, R-PA, G-PA and B-PA defined by the bank insulating layer 160. Thus, in the display apparatus according to the embodiment of the present disclosure, a luminance deviation depending on the generation position of the light emitted from each pixel area PA, R-PA, G-PA and B-PA can be prevented.

A voltage applied to the upper electrode 330 of each pixel area PA, R-PA, G-PA and B-PA can be a same as a voltage applied to the upper electrode 330 of adjacent pixel area PA, R-PA, G-PA and B-PA. For example, the upper electrode 330 of each pixel area PA, R-PA, G-PA and B-PA can be electrically connected to the upper electrode 330 of adjacent pixel area PA, R-PA, G-PA and B-PA. The upper electrode 330 of each pixel area PA, R-PA, G-PA and B-PA can include a same material as the upper electrode 330 of adjacent pixel area PA, R-PA, G-PA and B-PA. The upper electrode 330 of each pixel area PA, R-PA, G-PA and B-PA can be formed by a same process as the upper electrode of adjacent pixel area PA, R-PA, G-PA and B-PA. For example, the upper electrode 330 of each pixel area PA, R-PA, G-PA and B-PA can be formed simultaneously with the upper electrode 330 of adjacent pixel area PA, R-PA, G-PA and B-PA. The upper electrode 330 of each pixel area PA, R-PA, G-PA and B-PA can be in direct contact with the upper electrode 330 of adjacent pixel area PA, R-PA, G-PA and B-PA. For example, the upper electrode 330 of each pixel area PA, R-PA, G-PA and B-PA can extend onto the bank insulating layer 160. For example, the upper electrode 330 can be formed in common to extend continuously across adjacent subpixels. Thus, in the display apparatus according to the embodiment of the present disclosure, a process of forming the upper electrode 330 in each pixel area PA, R-PA, G-PA and B-PA can be simplified. And, in the display apparatus according to the embodiment of the present disclosure, the luminance of the light emitted from the light-emitting device 300 of each pixel area PA, R-PA, G-PA and B-PA can be adjusted by the data signal applied to the driving circuit DC of the corresponding pixel area PA, R-PA, G-PA and B-PA.

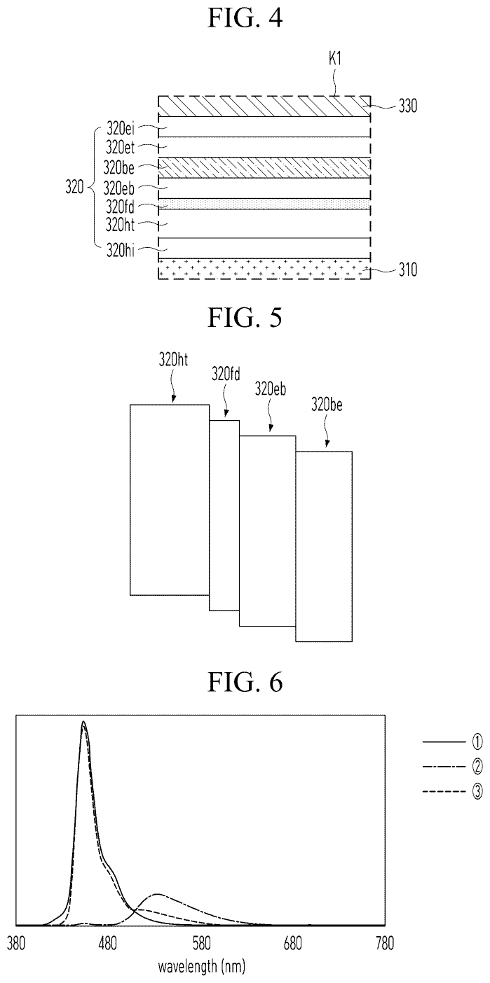

The light emitted from the light-emitting device 300 of each pixel area PA, R-PA, G-PA and B-PA can display a different color from the light emitted from the light-emitting device 300 of adjacent pixel area PA, R-PA, G-PA and B-PA. For example, each of the pixel areas PA, R-PA, G-PA and B-PA can be one of a red pixel area R-PA in which the light displaying red color is emitted, a blue pixel area B-PA in which the light displaying blue color is emitted, and a green pixel area G-PA in which the light displaying green color is emitted. At least some of the light-emitting unit 320 of each pixel area PA, R-PA, G-PA and B-PA can be separated from the light-emitting unit 320 of adjacent pixel area PA, R-PA, G-PA and B-PA. For example, the emission material layer (EML) of each pixel area PA, R-PA, G-PA and B-PA can be spaced apart from the light-emitting unit 320 of adjacent pixel area PA, R-PA, G-PA and B-PA. At least some of the layers constituting the light-emitting unit 320 of each pixel areas PA, R-PA, G-PA and B-PA can include an end portion on the bank insulating layer 160. The light-emitting unit 320 having a stacked structure different from that of the adjacent pixel areas PA, R-PA, G-PA and B-PA can be disposed on at least one of the pixel areas PA, R-PA, G-PA and B-PA. For example, in the display apparatus according to the embodiment of the present disclosure, the light-emitting unit 320 of the blue pixel area B-PA can include a hole injection layer 320hi, a hole transport layer 320ht, an anti-degradation layer 320fd, an electron blocking layer 320eb, a blue emission material layer 320be, an electron transport layer 320et and an electron injection layer 320ei, as shown in FIG. 4.

The blue emission material layer 320be can generate light using holes supplied through the hole injection layer 320hi, the hole transport layer 320ht, the anti-degradation layer 320fd and the electron blocking layer 320eb from the lower electrode 310 and electrons supplied through the electrode injection layer 320ei and the electrode transport layer 320et from the upper electrode 330. The blue emission material layer 320be can include a blue host and a blue dopant doped in the blue host. The blue dopant can be a fluorescent dopant. For example, the blue host of the blue emission material layer 320be can include one of the naphthalene moiety, anthracene, pyrene and phenanthrene, and the blue dopant of the blue emission material layer 320be can be a pyrene-based or boron-based blue fluorescent dopant.

The electron blocking layer 320eb between the hole transport layer 320ht and the blue emission material layer 320be can block electrons supplied to the blue emission material layer 320be and/or excitons generated in the blue emission material layer 320be from moving toward the hole transport layer 320ht. For example, a LUMO energy level of the electron blocking layer 320eb can be higher than a LUMO energy level of the blue emission material layer 320be, as shown in FIG. 5. In this way, the combinations of holes and electrons can be concentrated at the blue emission material layer 320be. Here, since a LUMO energy level is based on the vacuum level, the expression that ‘the LUMO energy level is high’ means that the absolute value of the LUMO energy level is small. That is, in the display apparatus according to the embodiment of the present disclosure, the LUMO energy level of the electron blocking layer 320eb can have an absolute value smaller than the LUMO energy level of the blue emission material layer 320be.

The HOMO energy level of the electron blocking layer 320eb can be lower than the HOMO energy level of the hole transport layer 320ht. Here, since a HOMO energy level is based on the vacuum level, the expression that ‘the HOMO energy level is low’ means that the absolute value of the HOMO energy level is great. That is, in the display apparatus according to the embodiment of the present disclosure, the HOMO energy level of the electron blocking layer 320eb can have an absolute value greater than the HOMO energy level of the hole transport layer 320ht. Thus, in the display apparatus according to the embodiment of the present disclosure, holes passing through the hole transport layer 320ht having relatively high hole transfer characteristics may not flow smoothly into the electron blocking layer 320b, due to the difference in HOMO energy levels between the hole transport layer 320ht and the electron blocking layer 320eb. In other words, due to the energy band gap between hole transport layer 320ht and the electron blocking layer 320b, the flow of holes can be impaired or impeded, which may lead to combinations between holes and electrons occurring in a layer other than the blue emission material layer 320be, which can degrade the light emitting unit faster and reduce the lifespan of the display device.

The anti-degradation layer 320fd between the hole transport layer 320ht and the electron blocking layer 320eb can be made of a fluorescent dopant in which an amine monomer is substituted in a core. The anti-degradation layer 320fd can have a single-layer structure. The anti-degradation layer 320fd can be formed of a single material. The anti-degradation layer 320fd may not include a host. For example, a plurality of fluorescent dopants in which an amine monomer is substituted in the core can be stacked on a surface of the hole transport layer 320ht toward the electron blocking layer 320eb, to form the anti-degradation layer 320fd. Thus, in the display apparatus according to the embodiment of the present disclosure, the anti-degradation layer 320fd can have a relatively high hole transfer characteristics by the amine monomer of the fluorescent dopant. For example, in the display apparatus according to the embodiment of the present disclosure, the HOMO energy level of the anti-degradation layer 320fd can be between the HOMO energy level of the hole transport layer 320ht and the HOMO energy level of the electron blocking layer 320eb. In other words, the HOMO energy level of the anti-degradation layer 320fd can soften the transition between the energy band gap between hole transport layer 320ht and the electron blocking layer 320b, so that holes and electrons can be more easily concentrated at the blue emission material layer 320be. The hole transport layer 320ht and the electron blocking layer 320eb can be formed of a different material from the anti-degradation layer 320fd. For example, the anti-degradation layer 320gd can have a smaller thickness than the hole transport layer 320ht and the electron blocking layer 320eb. Therefore, in the display apparatus according to the embodiment of the present disclosure, the delay in movement of holes due to the difference in the HOMO energy level between the hole transport layer 320ht and the electron blocking layer 320eb can be alleviated by the anti-degradation layer 320fd. That is, in the display apparatus according to the embodiment of the present disclosure, holes passing through the hole transport layer 320ht can flow more smoothly into the electron blocking layer 320eb by the anti-degradation layer 320fd. And, in the display apparatus according to the embodiment of the present disclosure, efficiency of the blue emission material layer 320be can be improved. In this way, holes and electrons can flow more equally from the anode and cathode to arrive at the blue emission material layer 320be for combination to emit excitons.

In addition, excitons can be generated by recombining electrons passing through the electron blocking layer 320eb with holes introduced through the hole transport layer 320ht in the anti-degradation layer 320fd. Thus, in the display apparatus according to the embodiment of the present disclosure, the fluorescent dopant of the anti-degradation layer 320fd can generate light by excitons generated in the anti-degradation layer 320fd and/or excitons passing through the electron blocking layer 320eb. That is, in the display apparatus according to the embodiment of the present disclosure, holes and/or electrons may not be accumulated between the hole transport layer 320ht and the electron blocking layer 320eb. In other words, the anti-degradation layer 320fd can also act as a type of auxiliary emission layer, in which if any holes and electrons happen to combine outside of the blue emission material layer 320be, than can have a safe space to combine within anti-degradation layer 320fd and still emit some light due to the fluorescent dopant of the anti-degradation layer 320fd. The light emitted from the anti-degradation layer 320fd can be blue light, but embodiments are not limited thereto. For example, the anti-degradation layer 320fd can emit a different color of light, such as green light. In this way, other layers (e.g., the hole transport layer and/or the electron blocking layer) can be protected from damage due to combinations of holes and electrons, and more light can be emitted out of the light emitting unit. Therefore, in the display apparatus according to the embodiment of the present disclosure, damage of the light-emitting unit 320 on the blue pixel area B-PA due to the accumulation of holes and/or electrons at the hole transport layer and/or the electron blocking layer can be prevented. And, in the display apparatus according to the embodiment of the present disclosure, life-time of the light-emitting unit 320 on the blue pixel area B-PA can be improved.

Light generated by the fluorescent dopant of the anti-degradation layer 320fd can be blue light, but it may not be blue light, according to embodiments. For example, the light generated by the fluorescent dopant of the anti-degradation layer 320fd can be green light or other colors of light. The fluorescent dopant of the anti-degradation layer 320fd can include a different material than the blue fluorescent dopant of the blue emission material layer 320be.

The fluorescent dopant of the anti-degradation layer 320fd can have a lower efficiency than the blue fluorescent dopant of the blue emission material layer 320be. For example, the fluorescent dopant of the anti-degradation layer 320fd can be an anthracene derivative in which an aromatic amine monomer is substituted in an anthracene core. That is, in the display apparatus according to the embodiment of the present disclosure, the fluorescent dopant of the anti-degradation layer 320fd can be a green fluorescent dopant represented by one of the formulas 1 to 3 below.

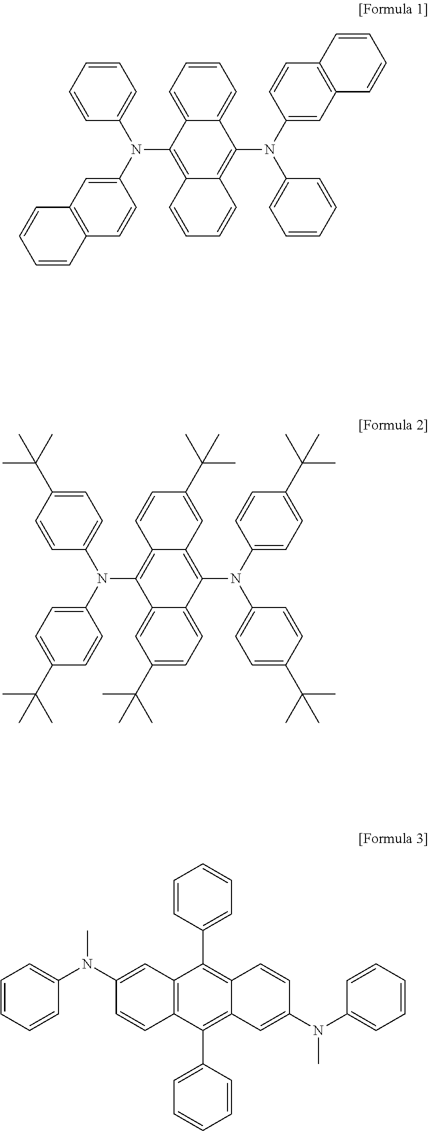 [SMILES: c1ccc(N(c2ccc3ccccc3c2)c2c3ccccc3c(N(c3ccccc3)c3ccc4ccccc4c3)c3ccccc23)cc1 ; CC(C)(C)c1ccc(N(c2ccc(C(C)(C)C)cc2)c2c3ccc(C(C)(C)C)cc3c(N(c3ccc(C(C)(C)C)cc3)c3ccc(C(C)(C)C)cc3)c3ccc(C(C)(C)C)cc23)cc1 ; CN(c1ccccc1)c1ccc2c(-c3ccccc3)c3cc(N(C)c4ccccc4)ccc3c(-c3ccccc3)c2c1]

Table 1 below shows a driving voltage, an external quantum efficiency (EQE), an intensity of light and a life-time (T95) of a blue pixel area (Comparative example) in which the light-emitting unit 320 of the light-emitting device 300 does not include the anti-degradation layer 320fd, a blue pixel area (Experimental example 1) in which the light-emitting unit 320 of the light-emitting device 300 includes the anti-degradation layer 320fd having a thickness of 30 Å, and a blue pixel area (Experimental example 2) in which the light-emitting unit 320 of the light-emitting device 300 includes the anti-degradation layer 320fd having a thickness of 50 Å. Here, the fluorescent dopant of the anti-degradation layer 320fd in Experimental examples 1 and 2 is a green fluorescent dopant green fluorescent dopant represented by one of the formulas 1 to 3, and T95 means time until the luminance decreases to 95% of the initial value.

TABLE 1

| | IVL@10 mA/cm² | | | |
|---|---|---|---|---|
| | Volt(V) | EQE | intensity | T95 |
| Comparative | 0 | 100% | 100% | 100% |
| example | | | | |
| Experimental | −0.16 | 114% | 100% | 131% |
| example 1 | | | | |
| Experimental | −0.21 | 108% | 94% | 137% |
| example 2 | | | | |

Referring to Table 1, if the light-emitting unit 320 in the blue pixel area includes the anti-degradation layer 320fd, the driving voltage of the blue pixel area can be reduced, and efficiency and life-time of the blue pixel area can be improved. For example, the anti-degradation layer 320fd can allow for smoother and easier combination of holes and electrons at the blue emission material layer 320be, even if a few holes and a few electrons combine together at the anti-degradation layer 320fd. Thus, in the display apparatus according to the embodiment of the present disclosure, the light-emitting unit 320 of the blue pixel area B-PA can include the anti-degradation layer 320fd between the hole transport layer 320ht and the electron blocking layer 320eb, and the anti-degradation layer 320fd can include the fluorescent dopant in which an amine monomer is substituted in a core, such that efficiency and life-time of the blue pixel area B-PA can be improved, as shown in FIGS. 2 to 5. And, referring to Table 1, the Experimental example 2 can have a reduced intensity than the Comparative example and the Experimental example 1. Therefore, in the display apparatus according to the embodiment of the present disclosure, the anti-degradation layer 320fd of the light-emitting unit 320 on the blue pixel area B-PA can have a thickness of 50 Å or less, preferably 30 Å to 50 Å (e.g., 40 Å), such that efficiency and life-time of the blue pixel area B-PA can be improved, without reducing the intensity of the light emitted from the blue pixel area B-PA, e.g., to provide an optical balance between brightness and lifespan.

FIG. 6 is a graph showing relative intensity according to a wavelength of light \textcircled{1} emitted from a first blue pixel area in which the light-emitting unit 320 does not include the anti-degradation layer 320fd, light \textcircled{2} emitted from a second blue pixel area in which the light-emitting unit 320 includes the anti-degradation layer 320fd between the electron blocking layer 320eb and the blue emission material layer 320be, and light \textcircled{3} emitted from a third blue pixel area in which the light-emitting unit 320 includes the anti-degradation layer 320fd between the hole transport layer 320ht and the electron blocking layer 320eb.

Referring to FIG. 6, the light \textcircled{3} emitted from the third blue pixel area is not significantly different from the light \textcircled{1} emitted from the first blue pixel area, but the light \textcircled{2} emitted from the second blue pixel area can be significantly reduced in the peak of the wavelength range corresponding to blue color and may cause too much of a color shift when compared to the light \textcircled{1} emitted from the first blue pixel area. That is, when the anti-degradation layer 320fd is in direct contact with the blue emission material layer 320be, excitons generated in the emission material layer 320be can move into the anti-degradation layer 320fd, so that efficiency of the blue emission material layer 320be can be significantly reduced. In other words, the anti-degradation layer 320fd can be slightly spaced apart from the emission material layer 320be by at least one other layer so that the anti-degradation layer 320fd does not dominate the formation of excitons. In this way, the majority of excitons can still be concentrated at the blue emission material layer 320be. Thus, in the display apparatus according to the embodiment of the present disclosure, the electron blocking layer 320eb of the blue pixel area B-PA can be disposed between the anti-degradation layer 320fd and the blue emission material layer 320be of the blue pixel area B-PA, such that the decrease in efficiency of the blue pixel area B-PA due to the anti-degradation layer 320fd can be prevented. In this way, holes and electrons can more easily flow towards each other, and the majority of holes and electrons can be combined at the blue emission material layer 320be. In other words, the anti-degradation layer 320fd may emit a very small amount of green light, but its inclusion within the stack can allow for the majority holes and electrons to flow easier and combine at the blue emission material layer 320be, while also avoiding combinations at other layers that are more susceptible to damage, such as the hole transport layer and/or the electron blocking layer. Therefore, in the display apparatus according to the embodiment of the present disclosure, efficiency and life-time of the blue pixel area B-PA can be effectively improved.

In the display apparatus according to the embodiment of the present disclosure, an encapsulation structure 400 can be disposed on the light-emitting device 300 of each pixel area PA, R-PA, G-PA and B-PA, as shown in FIG. 3. The encapsulation structure 400 can prevent damage of the light-emitting device 300 of each pixel area PA, R-PA, G-PA and B-PA due to external moisture and impact. The encapsulation structure 400 can have a multi-layer structure. For example, the encapsulation structure 400 can include a first encapsulating layer 410, a second encapsulating layer 420 and a third encapsulating layer 430, which are sequentially stacked. The first encapsulating layer 410, the second encapsulating layer 420 and the third encapsulating layer 430 can include an insulating material. The second encapsulating layer 420 can include a different material from the first encapsulating layer 410 and the third encapsulating layer 430. For example, the first encapsulating layer 410 and the third encapsulating layer 430 can include an inorganic insulating material, and the second encapsulating layer 420 can include an organic insulating material. Thus, in the display apparatus according to the embodiment of the present disclosure, damage of the light-emitting device 300 of each pixel area PA, R-PA, G-PA and B-PA due to the external moisture and impact can be effectively prevented. A thickness difference due to the light-emitting device 300 of each pixel area PA, R-PA, G-PA and B-PA can be removed by the second encapsulating layer 420. For example, a thickness of the second encapsulating layer 420 can be greater than a thickness of the first encapsulating layer 410 and a thickness of the third encapsulating layer 430. An upper surface of the encapsulation structure 400 opposite to the device substrate 100 can be parallel to the upper surface of the device substrate 100.

Accordingly, the display apparatus according to the embodiment of the present disclosure can include the light-emitting device 300 on each pixel area PA, R-PA, G-PA and B-PA, in which the light-emitting device 300 can include the light-emitting unit 320 between the lower electrode 310 and the upper electrode 330, in which the light-emitting unit 320 of the blue pixel area B-EA can include the electron blocking layer 320eb between the hole transport layer 320ht and the blue emission material layer 320be, and the anti-degradation layer 320fd between the hole transport layer 320ht and the electron blocking layer 320eb, and in which the anti-degradation layer 320fd can be made of the fluorescent dopant in which an amine monomer is substituted in a core. Thus, in the display apparatus according to the embodiment of the present disclosure, damage of the light-emitting unit 320 on the blue pixel area B-PA due to the accumulated holes and the accumulated electrons can be prevented. That is, in the display apparatus according to the embodiment of the present disclosure, efficiency and life-time of the blue pixel area B-PA can be improved without reducing the intensity of light emitted from the blue pixel area B-PA. Therefore, in the display apparatus according to the embodiment of the present disclosure, the quality of the image provided to the user can be improved.

The display apparatus according to the embodiment of the present disclosure can include color filters 500R, 500B and 500G disposed on a path of light emitted from the light-emitting device 300 of each pixel area R-PA, G-PA and B-PA. For example, in the display apparatus according to the embodiment of the present disclosure, the color filter 500R, 500B and 500G of each pixel area R-PA, G-PA and B-PA can be disposed on the encapsulation structure 400, as shown in FIG. 3. The color filter 500R, 500B and 500G of each pixel area R-PA, G-PA and B-PA can display a color in which the corresponding pixel area R-PA, G-PA and B-PA realizes by using the light emitted from the light-emitting device 300 of the corresponding pixel area R-PA, G-PA and B-PA. For example, the color filters 500R, 500B and 500G can include a red color filter 500R in the red pixel area R-PA, a blue color filter 500B in the blue pixel area B-PA, and a green color filter 500G in the green pixel area G-PA. The emission area of each pixel area R-PA, G-PA and B-PA can have a smaller size than the color filter 500R, 500B and 500G of the corresponding pixel area R-PA, G-PA and B-PA. For example, the color filter 500R, 500B and 500G of each pixel area R-PA, G-PA, B-PA can have a larger width than a portion of the corresponding lower electrode 310 exposed by the bank insulating layer 160. Thus, in the display apparatus according to the embodiment of the present disclosure, light leakage due to light that did not pass through the color filter 500R, 500G and 500B of each pixel area R-PA, B-PA and G-PA can be prevented. And, in the display apparatus according to the embodiment of the present disclosure, the color reproducibility can be improved by the light generated in the anti-degradation layer 320fd of the blue pixel area B-PA.

A filter passivation layer 600 can be disposed on the color filter 500R, 500G and 500B of each pixel area R-PA, G-PA and B-PA. The filter passivation layer 600 can prevent damage of the color filters 500R, 500G and 500B due to the external impact and moisture. For example, the color filter 500R, 500G and 500B of each pixel area R-PA, G-PA and B-PA can be completely covered by the filter passivation layer 600. The filter passivation layer 600 can include an insulating material. For example, the filter passivation layer 600 can include at least one of inorganic insulating material and organic insulating material. The filter passivation layer 600 can have a multi-layer structure. For example, the filter passivation layer 600 can have a structure in which an inorganic insulating layer made of inorganic insulating material is formed on an organic insulating layer made of organic insulating material. A thickness difference due to the color filters 500R, 500G and 500B can be removed by the filter passivation layer 600. Thus, in the display apparatus according to the embodiment of the present disclosure, the damage of the color filter 500R, 500G and 500B on each pixel area R-PA, G-PA and B-PA due to the external impact and moisture can be effectively prevented.

The display apparatus according to the embodiment of the present disclosure is described that the driving circuit DC of each pixel area PA, R-PA, G-PA and B-PA consists of the first thin film transistor TR1, the second thin film transistor TR2 and the storage capacitor Cst. However, in the display apparatus according to another embodiment of the present disclosure, the driving circuit DC of each pixel area PA, R-PA, G-PA and B-PA can include a driving thin film transistor and at least one switching thin film transistor. For example, in the display apparatus according to another embodiment of the present disclosure, the driving circuit DC of each pixel area PA, R-PA, G-PA and B-PA can further include a third thin film transistor for initializing the storage capacitor Cst of the corresponding pixel area PA, R-PA, G-PA and B-PA according to the gate signal. The third thin film transistor of each pixel area PA, R-PA, G-PA and B-PA can include a third semiconductor pattern, a third gate electrode, a third drain electrode and a third source electrode. The third semiconductor pattern of each pixel area PA, R-PA, G-PA and B-PA can include a semiconductor material. The third gate electrode of each pixel area PA, R-PA, G-PA and B-PA can be electrically connected to the corresponding gate line GL. The third drain electrode of each pixel area PA, R-PA, G-PA and B-PA can be electrically connected to an initial line applying an initial signal. The third source electrode of each pixel area PA, R-PA, G-PA and B-PA can be electrically connected to the storage capacitor Cst of the corresponding pixel area PA, R-PA, G-PA and B-PA. Thus, in the display apparatus according to another embodiment of the present disclosure, the degree of freedom in configuring each driving circuit DC can be improved.

In the display apparatus according to the embodiment of the present disclosure, the location and the electric connection of the first drain electrode, the first source electrode, the second drain electrodes 225 and the second source electrode 227 in each driving circuit DC can vary depending on the configuration of the corresponding driving circuit DC and/or the type of the corresponding thin film transistors TR1 and TR2. For example, in the display apparatus according to another embodiment of the present disclosure, the second gate electrode 223 of each driving circuit DC can be electrically connected to the first drain electrode of the corresponding driving circuit DC. Thus, in the display apparatus according to another embodiment of the present disclosure, the degree of freedom in the configuration of each driving circuit DC and the type of each thin film transistor TR1 and TR2 can be improved.

The display apparatus according to the embodiment of the present disclosure is described that the light generated by the anti-degradation layer 320fd of the blue pixel area B-PA can display a color other than blue color (e.g., green light). However, in the display apparatus according to another embodiment of the present disclosure, the anti-degradation layer 320fd of the blue pixel area B-PA can include a blue fluorescent dopant. The blue fluorescent dopant of the anti-degradation layer 320fd can be different from the blue fluorescent dopant of the blue emission material layer 320be. Thus, in the display apparatus according to another embodiment of the present disclosure, the color reproducibility of the blue light emitted from the blue pixel area B-PA can be improved.

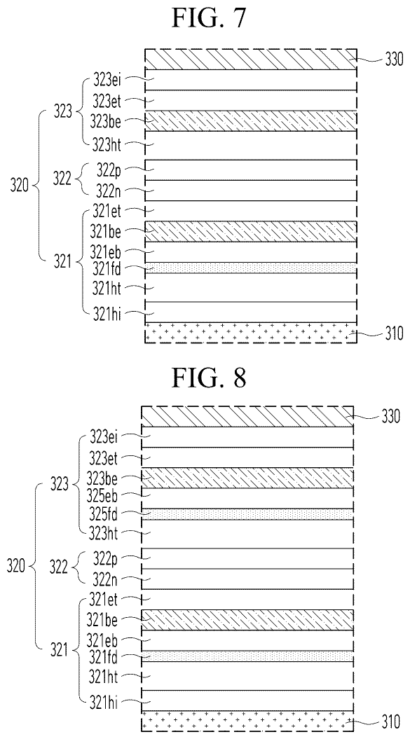

The display apparatus according to the embodiment of the present disclosure is described that the light-emitting unit 320 of each pixel area PA, R-PA, G-PA and B-PA can include a single emission material layer (EML). However, in the display apparatus according to another embodiment of the present disclosure, the light-emitting unit 320 of each pixel area PA, R-PA, G-PA and B-PA can include a plurality of emission material layers (EML). For example, with reference to FIG. 7, in the display apparatus according to another embodiment of the present disclosure, the light-emitting unit 320 of the blue pixel area can include a first emission stack 321, a charge generation layer 322 and a second emission stack 323, the first emission stack 321 can include an anti-degradation layer 321fd, an electron blocking layer 321eb and a first emission material layer 321be, and the second emission stack 323 can include a second emission material layer 323be.

Light generated by the second emission material layer 323be of the second emission stack 323 can have a wavelength range same as light generated by the first emission material layer 321be of the first emission stack 321. For example, the first emission material layer 321be and the second emission material layer 323be can include a same blue dopant. Thus, in the display apparatus according to another embodiment of the present disclosure, the color reproducibility, the efficiency and the life-time of each pixel area can be improved.

With reference to FIG. 8, in the display apparatus according to another embodiment of the present disclosure, the first emission stack 321 can include a first anti-degradation layer 321fd, a first electron blocking layer 321eb and a first emission material layer 321be, and the second emission stack 323 can include a second anti-degradation layer 323fd, a second electron blocking layer 323eb and a second emission material layer 323be. The first anti-degradation layer 321fd and the second anti-degradation layer 323fd can be made of the fluorescent dopant in which an amine monomer is substituted in a core. The fluorescent dopant of the first anti-degradation layer 321fd can have a lower efficiency than the blue dopant of the first emission material layer 321be. The fluorescent dopant of the second anti-degradation layer 323fd can have a lower efficiency than the blue dopant of the second emission material layer 323be. For example, the fluorescent dopant of the first anti-degradation layer 321fd and the fluorescent dopant of the second anti-degradation layer 323fd can be an anthracene derivative in which an aromatic amine monomer is substituted in an anthracene core. The fluorescent dopant of the second anti-degradation layer 323fd can include a different material from the fluorescent dopant of the first anti-degradation layer 321fd. For example, light generated by the second anti-degradation layer 323fd can display a different color from light generated by the first anti-degradation layer 321fd. In other words, two stacks can be included and each of the two stacks can include its own anti-degradation layer. Thus, in the display apparatus according to another embodiment of the present disclosure, the accumulation of holes and/or electrons in the light-emitting unit 320 including the blue emission material layer can be effectively prevented.

The display apparatus according to the embodiment of the present disclosure is described that the lower electrode 310 of each pixel area PA, R-PA, G-PA and B-PA can have a higher reflectance than the upper electrode 330 of the corresponding pixel area PA, R-PA, G-PA and B-PA. However, in the display apparatus according to another embodiment of the present disclosure, the lower electrode 310 of each pixel area PA, R-PA, G-PA and B-PA can have a higher transmittance than the upper electrode 330 of the corresponding pixel area PA, R-PA, G-PA and B-PA. For example, in the display apparatus according to another embodiment of the present disclosure, the lower electrode 310 of each pixel area PA, R-PA, G-PA and B-PA can be a transparent electrode made of a transparent conductive material, such as ITO and IZO, and the upper electrode 330 of each pixel area PA, R-PA, G-PA and B-PA can include a metal, such as aluminum (Al) and silver (Ag). Thus, in the display apparatus according to another embodiment of the present disclosure, the light generated by the light-emitting unit 320 of each pixel area PA, R-PA, G-PA and B-PA can be emitted outside through the lower electrode 310 of the corresponding pixel area PA, R-PA, G-PA and B-PA and the device substrate 100.

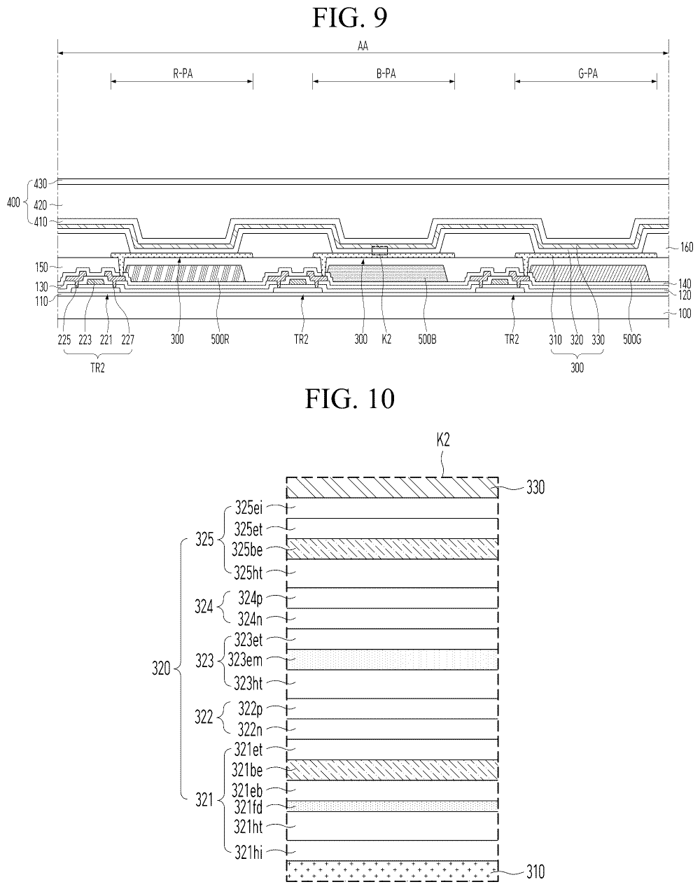

With reference to FIG. 9, in the display apparatus according to another embodiment of the present disclosure, the color filter 500R, 500B and 500G of each pixel area R-PA, G-PA and B-PA can be disposed between the device passivation layer 140 and the planarization layer 150 of the corresponding pixel area R-PA, G-PA and B-PA. A thickness difference due to the color filters 500R, 500G and 500B can be removed by the planarization layer 150. Thus, in the display apparatus according to another embodiment of the present disclosure, the degree of freedom in the location of the color filter 500R, 500G and 500B on each pixel area R-PA, G-PA and B-PA can be improved.

The display apparatus according to the embodiment of the present disclosure is described that the light emitted from the light-emitting device 300 of each pixel area PA, R-PA, G-PA and B-PA can display a different color from the light emitted from the light-emitting device 300 of adjacent pixel area PA, R-PA, G-PA and B-PA. However, in the display apparatus according to another embodiment of the present disclosure, the light emitted from the light-emitting device 300 of each pixel area PA, R-PA, G-PA and B-PA can display a same color as the light emitted from the light-emitting device 300 of adjacent pixel area PA, R-PA, G-PA and B-PA. For example, in the display apparatus according to another embodiment of the present disclosure, the light-emitting unit 320 of each pixel area R-PA, G-PA and B-PA can extend onto the lower electrode 310 of adjacent pixel area R-PA, G-PA and B-PA, as shown in FIG. 9. The light-emitting unit 320 of each pixel area R-PA, G-PA and B-PA can have a stacked structure same as the light-emitting unit 320 of adjacent pixel area R-PA, G-PA and B-PA. The light-emitting unit 320 of each pixel area R-PA, G-PA and B-PA can include emission stacks and at least one charge generation layer between the emission stacks. The charge generation layer can supply electrons or holes to adjacent emission stack. For example, the charge generation layer can have a stacked structure of a n-type charge generating layer and a p-type charge generating layer. Each of the emission stacks can generate and emit light.

At least one of the emission stacks in each pixel area R-PA, G-PA and B-PA can generate and emit blue light. The light emitted from the light-emitting device 300 of each pixel area R-PA, G-PA and B-PA can be white light. For example, in the display apparatus according to another embodiment of the present disclosure, the light-emitting unit 320 of each pixel area R-PA, G-PA and B-PA can include a first emission stack 321, a first charge generation layer 322, a second emission stack 323, a second charge generation layer 324 and a third emission stack 325, in which are sequentially stacked, a first emission material layer 321be of the first emission stack 321 and a third emission material layer 325be of the third emission stack 325 can be a blue emission material layer including a blue fluorescent dopant, and light generated by a second emission material layer 323em of the second emission stack 323 can display a color that is complementary to blue color, as shown in FIGS. 9 and 10. For example, the second emission material layer 323em can generate and emit light displaying yellow color.

Each of the charge generation layers 322 and 324 can have a stacked structure of a n-type charge generating layer 322n and 324n and a p-type charge generating layer 322p and 324p. For example, the first emission stack 321 can be disposed between the lower electrode 310 and the n-type charge generating layer 322n of the first charge generation layer 322, the second emission stack 323 can be disposed between the p-type charge generating layer 322p of the first charge generation layer 322 and the n-type charge generating layer 324n of the second charge generation layer 324, and the third emission stack 325 can be disposed between the p-type charge generating layer 324p of the second charge generation layer 324 and the upper electrode 330.

At least one of the first emission stack 321 and the third emission stack 325 can include the anti-degradation layer 321fd and the electron blocking layer 321eb. For example, the first emission stack 321 can include a hole injection layer 321hi, a first hole transport layer 321ht, an anti-degradation layer 321gd, an electron blocking layer 321eb, a first emission material layer 321be and a first electron transport layer 321et, in which are sequentially stacked, the second emission stack 323 can include a second hole transport layer 323ht, a second emission material layer 323em and a second electron transport layer 323et, in which are sequentially stacked, and the third emission stack 325 can include a third hole transport layer 325ht, a third emission material layer 325be, a third electron transport layer 325et and an electron injection layer 325ei, in which are sequentially stacked. Thus, in the display apparatus according to another embodiment of the present disclosure, the accumulation of holes and/or electrons in the first emission stack 321 disposed close to the lower electrode 310 can be prevented by the anti-degradation layer 321fd. Therefore, in the display apparatus according to another embodiment of the present disclosure, the efficiency and the life-time of each pixel area R-PA, B-PA and G-PA can be improved.

Also, in the display apparatus according to another embodiment of the present disclosure, luminance of the light provided to the color filter 500R, 500B and 500G of each pixel area R-PA, B-PA and G-PA can be increased by the light generated by the anti-degradation layer 321fd of the corresponding pixel area R-PA, B-PA and G-PA. For example, in the display apparatus according to another embodiment of the present disclosure, luminance of white light emitted from the light-emitting device 300 of each pixel area R-PA, B-PA and G-PA. Therefore, in the display apparatus according to another embodiment of the present disclosure, the efficiency of each pixel area R-PA, B-PA and G-PA can be further improved.

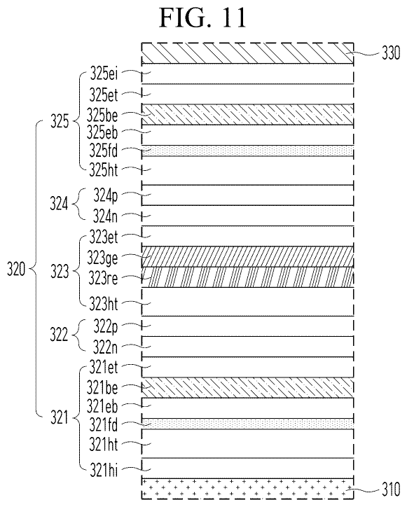

With reference to FIG. 11, in the display apparatus according to another embodiment of the present disclosure, the second emission stack 323 can include a plurality of emission material layer 323em. For example, in the display apparatus according to another embodiment of the present disclosure, a red emission material layer 323re and a green emission material layer 323ge can be stacked between the second hole transport layer 323ht and the second electron transport layer 323et of the second emission stack 323. For example, FIG. 11 is similar to the stacked configuration in FIG. 8, but the red emission material layer 323re and the green emission material layer 323ge are additionally included between the two stacks, and two charge generation layers are included.

The red emission material layer 323re can include a red host and a red dopant doped in the red host. The red dopant can be a phosphorescent material. For example, the red host of the red emission material layer 323re can include CBP(carbazole biphenyl) or mCP(1,3-bis(carbazol-9-yl), and the red dopant of the red emission material layer 323re can be a red phosphorescent dopant including at least one selected from the group consisting of Ir(Piq)3(Tris(1-phenylisoquinoline)iridium(III)), Ir(piq)2(acac)(Bis(1-phenylisoquinoline)(acetylacetonate)iridiumIII)), Ir(btp)2(acac)(Bis)2-benzo[b]thiophen-2-yl-pyridine)(acetylacetonate)iridiumIII)), Ir(BT)2(acac)(Bis(2-phenylbenzothazolato)(acetylacetonate)iridiumIII)).

The green emission material layer 323ge can include a green host and a green dopant doped in the green host. The green dopant can be a phosphorescent material. For example, the green host of the green emission material layer 323ge can include CBP(carbazole biphenyl) or mCP(1,3-bis(carbazol-9-yl), and the green dopant of the green emission material layer 323ge can be a green phosphorescent dopant including at least one selected from the group consisting of Ir(ppy)3(fac tris(2-phenylpyridine)iridium), Ir(ppy)2(acac), Ir(mpyp)3. Thus, in the display apparatus according to another embodiment of the present disclosure, the efficiency and the color reproducibility of white light emitted from the light-emitting device 300 of each pixel area R-PA, B-PA and G-PA can be improved.

In the display apparatus according to another embodiment of the present disclosure, both of the first emission stack 321 and the third emission stack 325 in each pixel area R-PA, B-PA and G-PA can include the anti-degradation layer 321fd and the electron blocking layer 321eb. For example, in the display apparatus according to another embodiment of the present disclosure, the first emission stack 321 can include a hole injection layer 321hi, a first hole transport layer 321ht, a first anti-degradation layer 321gd, a first electron blocking layer 321eb, a first emission material layer 321be and a first electron transport layer 321et, in which are sequentially stacked, and the third emission stack 325 can include a third hole transport layer 325ht, a second anti-degradation layer 325gd, a second electron blocking layer 325eb, a third emission material layer 325be, a third electron transport layer 325et and an electron injection layer 325ei, in which are sequentially stacked, as shown in FIG. 11.

The first anti-degradation layer 321fd and the second anti-degradation layer 325fd can be made of fluorescent dopant in which an amine monomer is substituted in a core. The fluorescent dopant of the first anti-degradation layer 321fd can have a lower efficiency than the blue dopant of the first emission material layer 321be. The fluorescent dopant of the second anti-degradation layer 325fd can have a lower efficiency than the blue dopant of the third emission material layer 325be. For example, the fluorescent dopant of the first anti-degradation layer 321fd and the fluorescent dopant of the second anti-degradation layer 325fd can be an anthracene derivative in which an aromatic amine monomer is substituted in an anthracene core. The fluorescent dopant of the second anti-degradation layer 325fd can include a same material as the fluorescent dopant of the first anti-degradation layer 321fd, but embodiments are not limited thereto and different dopants can be included in the first and second anti-degradation layers 321fd and 325fd. Light generated by the second anti-degradation layer 325fd can display a same color as light generated by the first anti-degradation layer 321fd. For example, the fluorescent dopant of the first anti-degradation layer 321fd and the fluorescent dopant of the second anti-degradation layer 325fd can be a green fluorescent dopant represented by one of the formulas 1 to 3. Thus, in the display apparatus according to another embodiment of the present disclosure, the accumulation of holes and/or electrons in the first emission stack 321 and the third emission stack 325, which include a blue emission material layer can be prevented. Therefore, in the display apparatus according to another embodiment of the present disclosure, the efficiency and the life-time of each pixel area R-PA, B-PA and G-PA can be effectively improved.

Light generated by the third emission material layer 325be can have a wavelength range same as light generated by the first emission material layer 321be. For example, the blue fluorescent dopant of the third emission material layer 325be can include a same material as the blue fluorescent dopant of the first emission material layer 321be. Thus, in the display apparatus according to another embodiment of the present disclosure, the efficiency and the color reproducibility of the light generated and emitted by each light-emitting unit 320 can be effectively improved.

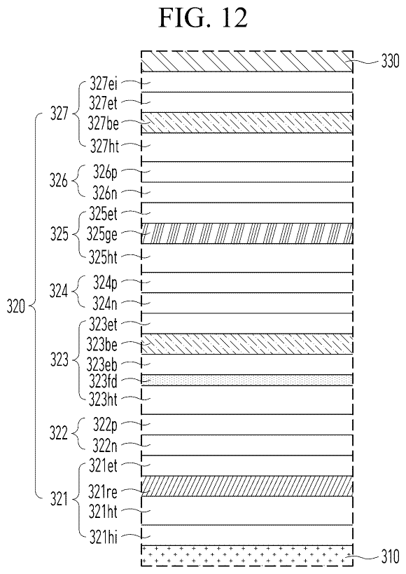

In addition, with reference to FIG. 12, in the display apparatus according to another embodiment of the present disclosure, an emission stack generating light displaying a color other than blue color can be disposed between the lower electrode and the emission stack including the blue emission material layer (e.g., red). For example, in the display apparatus according to another embodiment of the present disclosure, the light-emitting unit 320 of each pixel area can include a first emission stack 321 including a red emission material layer 321re, a second emission stack 323 including a first blue emission material layer 323be, a third emission stack 325 including a green emission material layer 325ge, and a fourth emission stack 327 including a second blue emission material layer 327be.

A first charge generation layer 322 can be disposed between the first emission stack 321 and the second emission stack 323. The second emission stack 323 can include an anti-degradation layer 323fd between a second hole transport layer 323ht and the first blue emission material layer 323be and an electron blocking layer 323eb between the anti-degradation layer 323gd and the first blue emission material layer 323be. A second charge generation layer 324 can be disposed between the second emission stack 323 and the third emission stack 325. A third charge generation layer 326 can be disposed between the third emission stack 325 and the fourth emission stack 327. Thus, in the display apparatus according to another embodiment of the present disclosure, the efficiency and the life-time of the light-emitting unit 320 can be effectively improved, regardless of the configuration of the light-emitting unit 320. Therefore, in the display apparatus according to another embodiment of the present disclosure, the degree of freedom for the configuration of the light-emitting unit 320 can be improved.

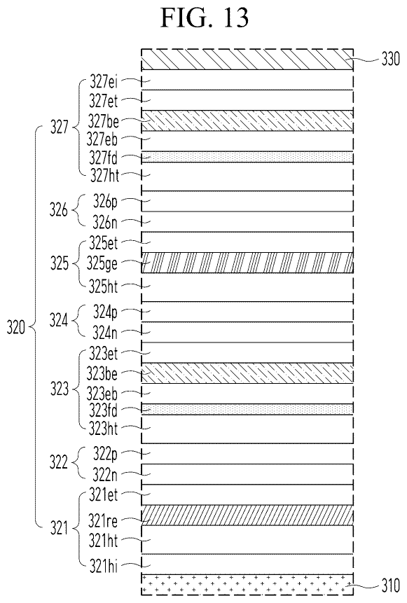

In addition, with reference to FIG. 13, the display apparatus according to another embodiment of the present disclosure, the second emission stack 323 can include a first anti-degradation layer 323fd, a first electron blocking layer 323eb and a first blue emission material layer 323be, and the fourth emission stack 327 can include a second anti-degradation layer 327fd, a second electron blocking layer 327eb and a second blue emission material layer 327be. The fluorescent dopant of the second anti-degradation layer 327fd can include a same material as the fluorescent dopant of the first anti-degradation layer 323fd. For example, the fluorescent dopant of the first anti-degradation layer 323fd and the fluorescent dopant of the second anti-degradation layer 327fd can be an anthracene derivative in which an aromatic amine monomer is substituted in an anthracene core. For example, a light emitting device within a subpixel can include seven stacks including three charge generation layers, two anti-degradation layers, two blue light emitting layers, a red light emitting layer and a green light emitting layer. Also, according to embodiments, the stacking order of the two blue light emitting layers, the red light emitting layer and the green light emitting layer can be variously changed according to designs and desired color hues. Also, a yellow emitting layer can be further included within the stacked configuration (e.g., similar to FIG. 10), but embodiments are not limited thereto. Thus, in the display apparatus according to another embodiment of the present disclosure, the efficiency and the color reproducibility of light emitted from each pixel area can be improved.

In the result, the display apparatus according to the embodiments of the present disclosure can comprise the light-emitting device on each pixel area, in which the light-emitting device can include the light-emitting unit between the lower electrode and the upper electrode, in which the light-emitting unit can include the electron blocking layer between the hole transport layer and the blue emission material layer and the anti-degradation layer between the hole transport layer and the electron blocking layer, and in which the anti-degradation layer include the fluorescent dopant in which an amine monomer is substituted in a core. Thus, in the display apparatus according to the embodiments of the present disclosure, the accumulation of holes and electrons in the light-emitting unit including the blue emission material layer can be prevented. That is, in the display apparatus according to the embodiments of the present disclosure, the damage of the light-emitting unit including the blue emission material layer due to the accumulated holes and the accumulated electrons can be prevented. Therefore, in the display apparatus according to the embodiments of the present disclosure, the efficiency and the life-time of the light-emitting device on each pixel area can be improved. And, in the display apparatus according to the embodiments of the present disclosure, power consumption can be reduced by low power driving.

What is claimed is:

1. A display apparatus comprising:
a light-emitting unit including a hole transport layer, an anti-degradation layer, an electron blocking layer and a blue emission material layer stacked on a lower electrode; and
an upper electrode disposed on the light-emitting unit, the upper electrode having a lower work-function than the lower electrode,
wherein the anti-degradation layer is disposed between the electron blocking layer and the hole transport layer,
wherein the blue emission material layer includes a blue dopant, and
wherein the anti-degradation layer is made of a fluorescent dopant in which an amine monomer is substituted in a core.

2. The display apparatus according to claim 1, wherein the anti-degradation layer is in contact with both of the hole transport layer and the electron blocking layer, and wherein the anti-degradation layer has a highest occupied molecular orbital (HOMO) energy level between a HOMO energy level of the hole transport layer and a HOMO energy level of the electron blocking layer.

3. The display apparatus according to claim 1, wherein a thickness of the anti-degradation layer is less than a thickness of the electron blocking layer.

4. The display apparatus according to claim 3, wherein the thickness of the anti-degradation layer is 30 Å to 50 Å.

5. The display apparatus according to claim 1, wherein the fluorescent dopant in the anti-degradation layer includes a different material from the blue dopant in the blue emission material layer.

6. The display apparatus according to claim 1, wherein the fluorescent dopant is an anthracene derivative in which an aromatic amine monomer is substituted in an anthracene core.

7. The display apparatus according to claim 5, wherein the fluorescent dopant is a green fluorescent dopant represented by one of formulas 1 to 3 below:

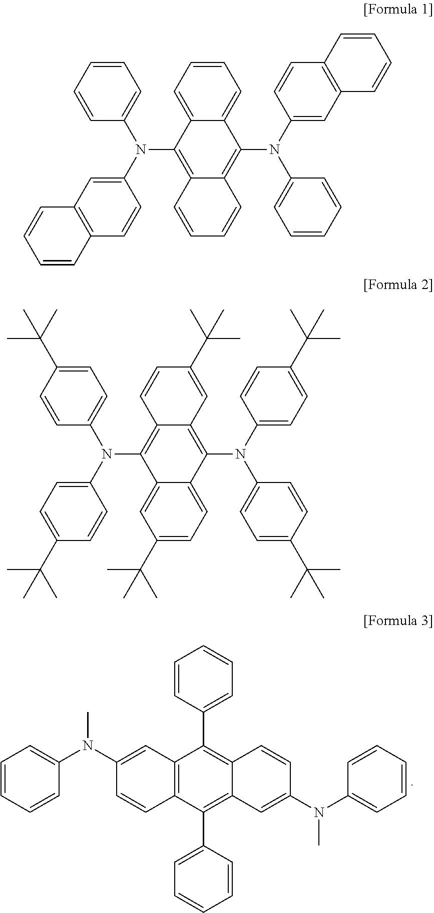 [SMILES: c1ccc(N(c2ccc3ccccc3c2)c2c3ccccc3c(N(c3ccccc3)c3ccc4ccccc4c3)c3ccccc23)cc1 ; CC(C)(C)c1ccc(N(c2ccc(C(C)(C)C)cc2)c2c3ccc(C(C)(C)C)cc3c(N(c3ccc(C(C)(C)C)cc3)c3ccc(C(C)(C)C)cc3)c3ccc(C(C)(C)C)cc23)cc1 ; CN(c1ccccc1)c1ccc2c(-c3ccccc3)c3cc(N(C)c4ccccc4)ccc3c(-c3ccccc3)c2c1]

8. The display apparatus according to claim 5, further comprising a blue color filter disposed on the upper electrode,
wherein a transmittance of the upper electrode is greater than a transmittance of the lower electrode.

9. A display apparatus comprising:
a first lower electrode disposed on a first pixel area of a substrate;
a light-emitting unit disposed on the first lower electrode;
an upper electrode disposed on the light-emitting unit; and
an encapsulation structure disposed on the upper electrode,
wherein the light-emitting unit includes a first emission stack, a second emission stack configured to emit light of a different color than the first emission stack, and a first charge generation layer between the first emission stack and the second emission stack,
wherein the first emission stack includes a first electron blocking layer between a first hole transport layer and a first blue emission material layer, and a first anti-degradation layer between the first hole transport layer and the first electron blocking layer, and
wherein the first anti-degradation layer includes a first fluorescent dopant in which an amine monomer is substituted in a core.

10. The display apparatus according to claim 9, wherein the second emission stack includes a green emission material layer having a green phosphorescent dopant, and a red emission material layer having a red phosphorescent dopant.

11. The display apparatus according to claim 9, wherein the light-emitting unit includes a third emission stack having a second blue emission material layer, and a second charge generation layer between the second emission stack and the third emission stack,
wherein each of the first blue emission material layer and the second blue emission material layer includes a blue dopant, and
wherein the blue dopant includes a different material than the first fluorescent dopant.

12. The display apparatus according to claim 11, wherein the blue dopant of the second blue emission material layer includes a same material as the blue dopant of the first blue emission material layer.

13. The display apparatus according to claim 11, wherein the third emission stack includes a second hole transport layer disposed on the second blue emission material layer, a second electron blocking layer between the second hole transport layer and the second blue emission material layer, and a second anti-degradation layer between the second hole transport layer and the second electron blocking layer, and
wherein the second anti-degradation layer includes a second fluorescent dopant in which an amine monomer is substituted in a core.

14. The display apparatus according to claim 13, wherein the second fluorescent dopant includes a same material as the first fluorescent dopant.

15. The display apparatus according to claim 9, further comprising:
a second lower electrode disposed on a second pixel area of the substrate;
a first color filter disposed on the encapsulation structure, the first color filter overlapping with an emission area of the first pixel area; and
a second color filter disposed on the second electrode, the second color filter overlapping with an emission area of the second pixel area,
wherein the light-emitting unit, the upper electrode and the encapsulation structure extend between the second lower electrode and the second color filter, and
wherein the second color filter includes a different material than the first color filter.

16. A light emitting device comprising:
a first emission material layer including a first type of dopant and configured to emit a first color of light;
an electron blocking layer configured to restrict a movement of electrons;
a hole transport layer configured to pass holes toward the first emission material layer; and
a first anti-degradation layer including a fluorescent dopant,
wherein the first anti-degradation layer is spaced apart from the first emission material layer, and
wherein the first anti-degradation layer is disposed between the electron blocking layer and the hole transport layer.

17. The light emitting device according to claim 16, wherein the fluorescent dopant of the first anti-degradation layer includes an amine monomer substituted in a core.

18. The light emitting device according to claim 16, wherein the first color of light is blue light,
wherein the first type of dopant in the first emission material is different than the fluorescent dopant in the first anti-degradation layer, and
wherein the first anti-degradation layer is configured to emit a second color of light different than the first color of light.

19. The light emitting device according to claim 16, wherein the first anti-degradation layer is configured to emit green light.

20. The light emitting device according to claim 16, further comprising:
a second emission material layer including the first type of dopant and configured to emit the first color of light;
a second anti-degradation layer including a second fluorescent dopant;
a third emission material layer configured to emit a second color of light different than the first color of light;
a fourth emission material layer configured to emit a third color of light different than the first color of light and the second color of light; and
one or more charge generation layers.
